(19) United States
(12) Patent Application Publication
(10) Pub. No.: US 2008/0029893 A1
(43) Pub. Date: Feb. 7, 2008

(54) Power and Ground Ring Layout

(75) Inventor: Chia-Lang CHANG, Chubei City (TW)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/780,789

(22) Filed: Jul. 20, 2007

Related U.S. Application Data
(60) Provisional application No. 60/835,882, filed on Aug. 7, 2006.

(51) Int. Cl. H01L 23/528

(52) U.S. Cl. 257/754; 257/E23.152

(57) ABSTRACT

An integrated circuit layout on a semiconductor substrate includes a plurality of circuit modules and power rails. One of the power rails is a positive voltage supply rail, and another one is a negative voltage supply rail or a ground rail. The positive voltage supply rail is located on a first layer of the semiconductor substrate. The negative voltage supply rail is located on a second layer of the semiconductor substrate. The second layer is located below the first layer. In this way, the integrated circuit layout area is reduced as negative voltage supply rail is moved to another layer.

### CROSS-REFERENCE TO RELATED APPLICATION

This application is a Non-Provisional of co-pending U.S. Provisional Application No. 60/835,882 filed on Aug. 7, 2006 by Chia-Lang Chang, entitled “POWER AND GROUND RING LAYOUT,” the entire contents of which is hereby incorporated by reference and for which priority is claimed under Title 35, United States Code § 119(e).

### BACKGROUND OF THE INVENTION

1. Field of the Invention

The inventions relate in general to integrated circuit design. More specifically, the inventions relate to power and ground routing in integrated circuit layout arrangements.

2. Background Art

There are two general methodologies used to determine the arrangements of structures in integrated circuit (IC) chips: top-down and bottom-up methodologies.

In the bottom-up methodology, the layout process is typically as follows. First, circuit gates are designed and arranged. Basic circuit components are then laid out around the gates. Circuit modules are then arranged and integrated into the various chip levels. Gate level analysis and simulation are performed on the circuit modules. Then, the same process is carried out at the whole chip level.

In the top-down methodology, design follows a different process: First, chip/system level factors and specifications are considered. A circuit floor plan is created taking into account model parameters of the various functional blocks. Functional circuit modules are designed, arranging circuit modules into functional blocks, and then functional level and chip/system level verifications are carried out.

Generally, the top-down design approach to IC design is the preferred method because the bottom-up design approach is harder to have the chip/system level specification met as lower functional blocks are put together. For example, in bottom-up design, the design layout of a chip level power grid (power supply rails and stripes) takes place after the design layout of lower level signal or wire layout. This creates complication for power planning engineers to optimally plan the layout of the power grid such that, for example, a minimum IR (voltage) drop is harder to achieve across the IC chip or die, due to package and die size or high level factors that were not considered earlier as in a top-down approach.

Power planning is critical in the design process of an IC die because the power grid of the IC die needs to be arranged in such a way to minimize IR drop, noise problems, and voltage swings, etc. IR drop in an IC die can cause signal propagation delays, high average power with the same circuit running speed, and noise created by voltage drops or ground rises in the power and/or ground grids.

One way to improve power distribution within an IC die is to increase the power grid density. In this manner, the distance between circuit components and the power supply pins, pads, or stripes can be made more uniform; thus yielding lower IR drops across the IC die. However, increasing the density of power grid is not without drawbacks. The power grid may take up a lot of space in the IC die, thus increasing the size of the die. An effect of this is an increase in the distance between circuit components which also increase the number of wire routings required to connect all of the circuit components.

Accordingly, what is needed is a power and/or ground grid planning scheme that would decrease the area of the IC die and at the same time maintain or improve the power grid density.

### SUMMARY

This section is for the purpose of summarizing some aspects of the inventions described more fully in other sections of this patent document. It briefly introduces some preferred embodiments. Simplifications or omissions may be made to avoid obscuring the purpose of the section. Such simplifications or omissions are not intended to limit the scope of the claimed inventions.

One aspect of the inventions relates to a layout for an integrated circuit on a semiconductor substrate. As an example, the layout includes a first and second metal layer. The first layer is located above the second layer. The first layer includes a first conductive grid pattern. The circuit module is connected to the first conductive grid pattern. The layout further includes a second conductive grid pattern that is identical to the first conductive grid pattern. The second conductive grid pattern is located on the second layer such that an image of the second conductive grid pattern substantially matches an image of the first conductive grid pattern above. Additionally, the circuit module is connected to the first/second conductive grid through vias and metals.

The first and the second conductive grid pattern of the IC layout may be positive and negative power supply grid patterns, respectively. Alternatively, the first and the second conductive grid patterns of the IC layout may be positive power supply grid pattern and a ground grid pattern, respectively. Or, the first and the second conductive grid patterns of the IC layout may be negative and positive power supply grid patterns, respectively.

Another aspect of the inventions relates to the shape of the conductive grid patterns. The first and second conductive grid patterns of the IC layout may be square-shaped, rectangular, Manhattan structured, or have some other suitable shape. As the “art” of integrated circuit fabrication advances, it could become possible to efficiently extend conductive grid patterns to have non-right angle turns in the conductive grids.

According to another aspect of the inventions, an integrated circuit layout on a semiconductor substrate comprises a first metal layer and a second metal layer located below the first metal layer. The first layer includes a plurality of positive power supply rails. Each of the circuit blocks is connected to at least one positive power supply rail through vias and metals. The second layer includes a plurality of negative power supply rails. A first of the plurality of negative power supply rails is routed such that it tracks a first of the plurality of positive power supply rails above it. Each of the circuit blocks is connected to at least one negative power supply rail through vias and metals.

Additional features and advantages of the inventions will be set forth in the description that follows, and in part will be apparent from the description, or may be learned by practice of the invention. The advantages of the invention will be realized and attained by the structure and particularly pointed out in the written description and claims hereof as well as the appended drawings.

The inventions can be implemented in numerous ways, including methods, systems, devices, and computer readable medium. Several embodiments of the inventions are discussed below. They are examples of how to practice the inventions, but not the only ways.

It is to be understood that both the foregoing general description and the following detailed description are exemplary and explanatory and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 illustrates a conventional layout of an integrated circuit.

FIG. 2 illustrates an enlarged view of an area of the integrated circuit shown in FIG. 1.

FIG. 3 illustrates a circuit layout of an integrated circuit according to an embodiment of the present invention.

FIG. 4 illustrates a side-cutout view of an integrated circuit.

FIG. 5 illustrates a side-cutout view of an integrated circuit according to an embodiment of the present invention.

FIG. 6 illustrates a circuit layout of an integrated circuit according to an embodiment of the present invention.

FIG. 7 schematically compares in perspective views traditional integrated circuit power layout with integrated circuit power layout according the inventions.

### DETAILED DESCRIPTION

This specification describes one or more embodiments that incorporate various features of the inventions. The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

An embodiment of the inventions is now described. While specific methods and configurations are discussed, it should be understood that this is done for illustration purposes only. A person skilled in the art will recognize that other configurations and procedures may be used without departing from the spirit and scope of the invention.

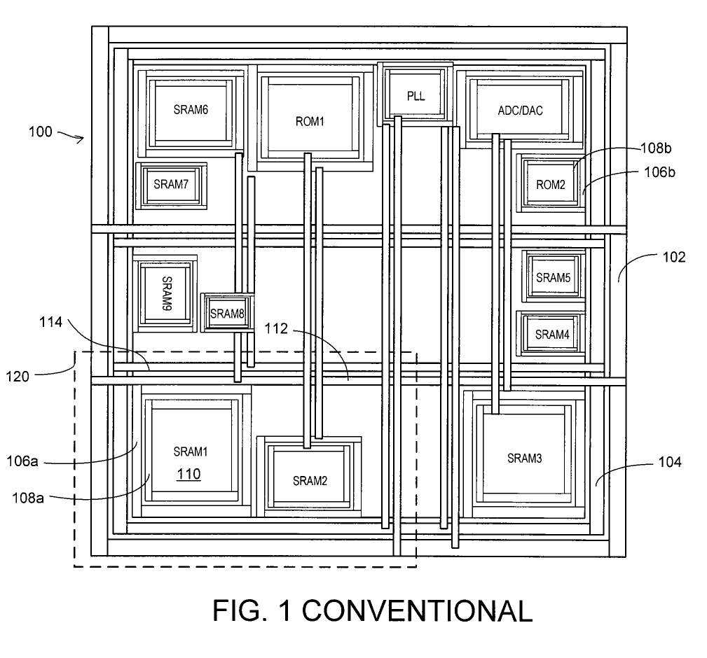

FIG. 1 illustrates a conventional layout of an IC die 100. IC die 100 includes a plurality of circuit modules such as SRAM and ROM modules. IC die 100 further includes other circuit components such as a PLL, an analog-to-digital converter, and various logic components. In IC die 100, power is distributed to all of the circuit components using a global power ring 102 (also known as a “global power rail”) and global ground ring 104 (also known as a “global ground rail”). Global power ring 102 and global ground ring 104 are connected to an external power source and ground, respectively. IC die 100 also includes a plurality of local power rings such as 106a-b and local ground rings such as 108a-b. Each of the local power and ground rings is connected to the global power and ground ring. In this way, power may be locally distributed to various circuit components.

As shown in FIG. 1, a SRAM 1 110 is powered and grounded by a power ring 106a and a ground ring 108a, respectively. Power ring 106a is connected to a power stripe 112, which is connected to global power ring 102 through vias and metals. Similarly, ground ring 108a is connected to a ground stripe 114 through vias and metals and a ground pad or metal routing located at a lower layer of IC die 100.

Additionally, global power ring 102 may be a positive (V_{dd}) power ring, and global ground ring 104 may be a negative (Vₛₛ) power ring. As shown in FIG. 1, power ring 102 and ground ring 104 run substantially parallel with each other. Similarly, local power rings and ground rings such as rings 106a and 108a also run in parallel with each other. This parallel V_{dd} and Vₛₛ ground layout arrangement is frequently used in IC layout. The parallel power-ground ring arrangement is convenient for power planning and distribution. In addition, it allows circuit design engineers to use a fewer number of layers for the layout of an IC die.

In this type of design, minimizing the number of layers used in the circuit designing and planning process is essential to keeping down the production cost of an IC die. This was especially important when available microfabrication processes were limited to 2 or 3 conductive metal layers. Today, various microfabrication processes are available that allow for the production of an IC die of more than 5 conductive metal layers. In addition, the production cost between an IC die with 2 or 3 layers and an IC die with 4 or more layers has also narrowed (especially true for high production IC die unit). Also signal routing (not power and ground routing) complexity itself only will require more than 2 to 3 layers of metal already, especially in modern highly integrated circuit designs. This development has allowed circuit design engineers to be more flexible and creative in their circuit planning and design, such as, for example, the power/ground ring/rail/trunk/strap layout structure implementation as described herein.

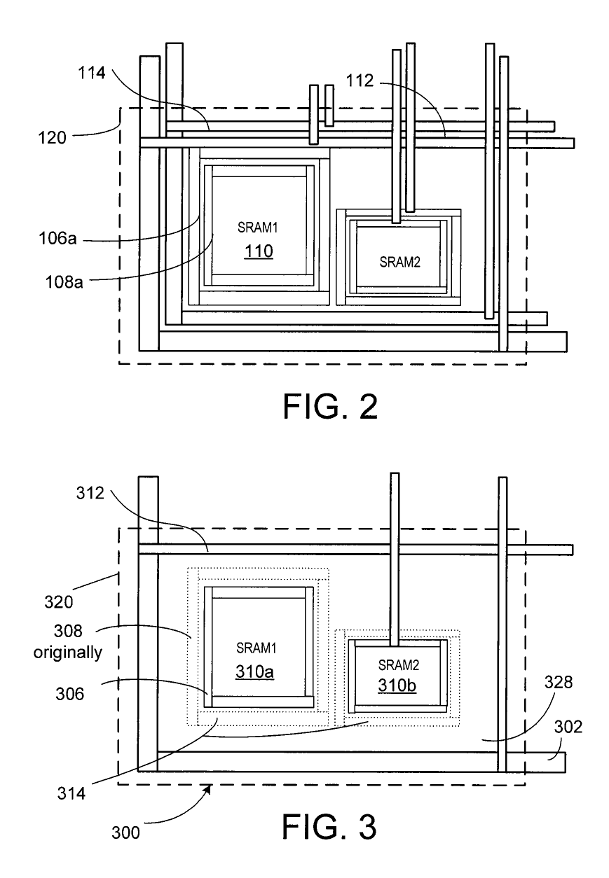

FIG. 2 illustrates an enlarged view of a portion 120 of circuit layout 100. FIG. 2 is provided to better illustrate the differences between circuit layout 100 and the circuit layout shown in FIG. 3, which will be discussed herein.

FIG. 3 illustrates a corresponding portion 320 of a circuit layout 300 according to an exemplary embodiment of the inventions. Circuit portion 320 bears the same relative relationship to circuit layout 300 as circuit portion 120 has with circuit layout 100. Although the entire layout of circuit layout 300 is not shown, it should be understood that the feature(s) described herein with respect to circuit portion 320 will also apply to the entire circuit layout 300. Circuit portion 320 shows a global power rail or ring 302, a plurality of circuit modules 310a and 310b, and a plurality of local power rings, i.e. power ring 306. Global power ring 302 is connected to an off-chip or external power supply. Power ring 302 provides power to various circuit components of circuit layout 300 such as circuit modules 310a and 310b by routing power to a power stripe 312. Power stripe 312 locally distributes power to a circuit module such as SRAM 310a through a bridge or with various other means such as vias/metals and another bridge at a lower substrate layer.

In circuit layout 300, power ring 302 is a positive power supply (V_{dd}) ring. In an alternative embodiment, power ring 302 is a negative power supply (Vₛₛ) ring. Similarly, local power ring 306 is a positive power supply (V_{dd}) ring. In an alternative embodiment, local power ring 306 is a negative power supply (Vₛₛ) ring. As shown in FIG. 3, area 328 is empty (not occupied). Empty area 328 is shown only for the purpose of illustration. Actual circuits, corresponding to circuit layout 300, produced in accordance with the principles of the inventions described herein will probably not have empty area 328 because power rail 302 will be moved substantially closer to a circuit area 314 (an empty area) such that the total surface area of circuit layout 300 is reduced as compared with circuit layout 100. This reduction of space reduces the size of the IC die and thus reduces the production cost. Alternatively, circuit area 314 may be expanded to the inner edge of power rail 302 to provide more space for circuit components while keeping the overall size of circuit layout 300 the same as circuit layout 100. In this manner, more circuit components could be added to circuit area 314 for added functionalities and features without increasing the overall size of circuit layout 300. However, the power/ground ring/rail/trunk/strip area can not be occupied with active circuitry which may contain transistors because transistors require a lot of signal routing. Common power/ground ring/rail/trunk/strip should generally not be allocated above the active circuitry area.

As shown in FIG. 2, ground ring 104 is present and is located on the same layer as global power ring 102. Ground ring 104 may alternatively be a negative power (Vₛₛ) supply ring for an IC die that includes circuit components requiring a dual supply power source. In FIG. 3, a ground ring similar to ground ring 104 is not present, thus yielding empty space 328. Although not shown in FIG. 3, a ground ring similar to ground ring 104 is moved to a lower layer. In this exemplary embodiment, global power rail or ring 302 is located on layer N and the ground ring is located on layer N−1 (below layer N). In an alternative embodiment, ring 302 is grounded and is located on layer N and a power ring is located on layer N−1.

Additionally, local power ring 306 is adjacent to module 310a, while an adjacent local ground ring is absent. As shown in FIG. 2, module 110 has both power ring 106a and ground ring 108a on the same layer. In the circuit layout 300, module 310a has its own local ground ring, but the local ground ring is located at a lower layer directly beneath local power ring 306. In an embodiment, all global power rings (e.g. ring 302), local power rings (e.g. ring 306), and stripes (e.g. stripe 312) on layer N have their respective copy of a ground ring located on layer N−1. In other words, the power grid pattern (all global and local power rings and stripes) on layer N is identical to the ground grid pattern on layer N−1. The ground grid pattern on layer N−1 is also located such that its image, if transposed, would match with the power grid pattern on layer N. In this manner, the power grid of circuit layout 300 can be made more dense as more space on layer N is available for power routing as well as the ground grid. This will also be easier for circuit designers to design a power grid such that power is uniformly distributed to various circuit components, thus leading to lower IR drops and heat dissipations.

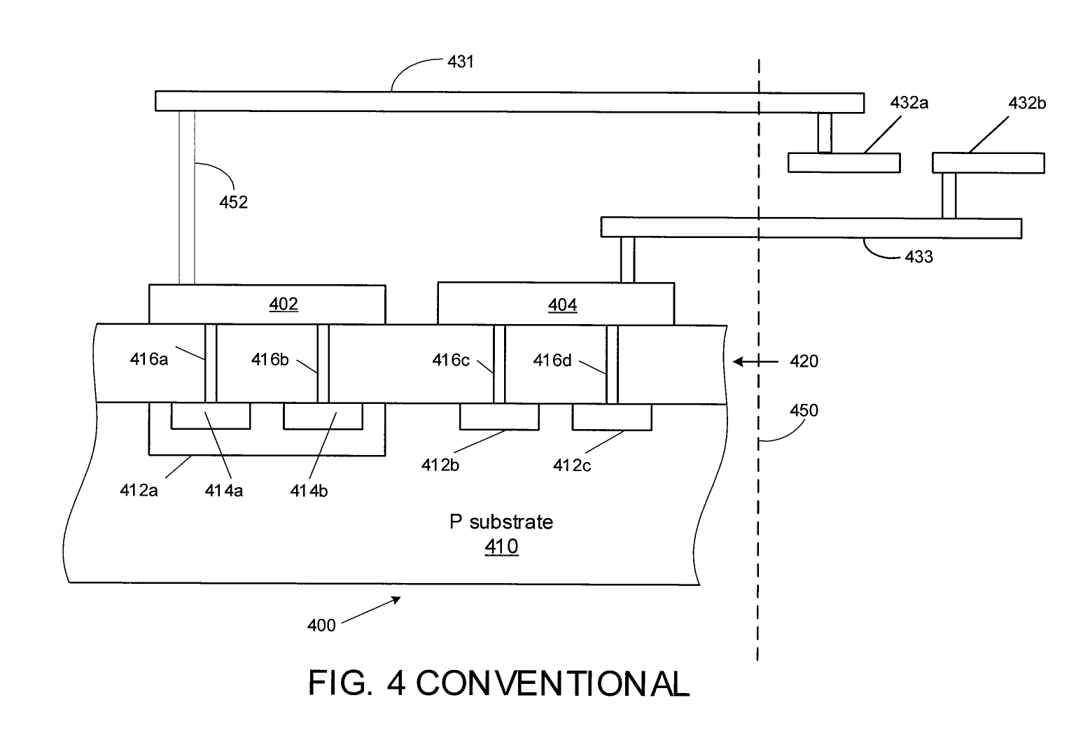

FIG. 4 illustrates an exemplary inner structure 400 of a semiconductor integrated circuit fabricated in accordance with conventional circuit layout 100 shown in FIG. 1. In this figure, transistor gates and other layout features are omitted for clarity so that the reader can easily see the power/ground elements. A main circuit area is defined by the region to the left of dashed line 450 and a power/grid ring structure area is defined by the region to the right of dashed line 450. The main circuit area may contain transistors. Structure 400 includes a power metal block 402, a ground metal block 404, a P-substrate layer 410, an insulating layer 420, N-well and N-doping portions 412a and 412b-c, respectively, P-doping portions 414a-b, and vias 416a-d. In a silicon based substrate, P-substrate 410 is produced by lightly doping the substrate with acceptor dopant (p-type) such as boron.

Alternatively, in a gallium arsenide based substrate, carbon, beryllium or zinc could be used as an acceptor dopant. N-well/doping portions 412a-c are made by first masking substrate layer 410 and leaving an area of substrate 410 exposed. The exposed area is then doped using N type dopant to form N-well/doping portions 412a-c. Power block 402 and ground block 404 are formed by depositing conductive materials such as copper onto insulating layer 420. Power block 402 is connected to the P well portions 414a and 414b by vias 416a and 416b, respectively. Vias 416a-d are also made with conductive materials such as copper. Similarly, ground block 404 is connected to N-well portions 412b and 412c through vias 416c and 416d, respectively.

The description above is for a circuit area which contains transistors. A power and ground (or negative power) structure area is conventionally added to be next to this circuit area and will have power and ground structure in parallel as illustrated in FIG. 4. The power and ground structures include metal lines 432a for power and 432b for ground. The space below the power and ground structure is useless because the metal layers must be used to feed power to at least 3 layers. The power distribution metal lines, in addition to lines 432a and 432b, must also include a metal line 433 for extending ground to the main circuit area to the left of dashed line 450. There is also required a metal line 431 to extend power connection to the main circuit area. Metal line 431 is connected to power rail 402 by a via 452. Main signal circuit routing is restricted beneath these power distribution metal lines.

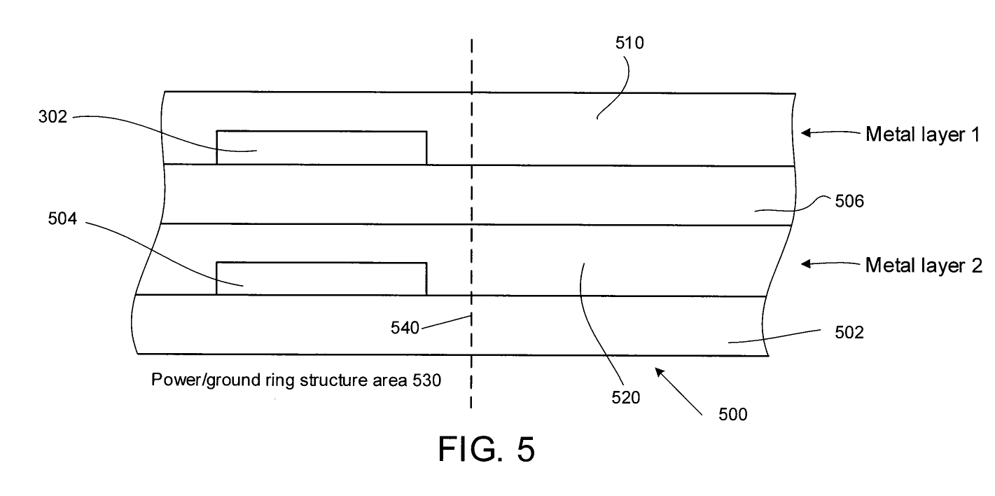

FIG. 5 illustrates an inner IC structure 500 of a semiconductor integrated circuit fabricated in accordance with the principles of the inventions and as shown in the circuit layout 300 of FIG. 3. Structure 500 includes a plurality of layers such as an insulating layer 502, an insulating layer 506, and metal layers 510 and 520 that are configured on top of one another as shown. Metal layer 510 includes global power rail/ring 302, and metal layer 520 includes a ground rail/ring 504. Insulating layer 506 is located between metal layer 510 and metal layer 520. Power rail/ring 302 and ground rail/ring 504 are located in a Power/ground ring structure area 530 bounded in FIG. 3 by a dotted line 540

In an alternative embodiment, ring 504 is a negative power (Vₛₛ) supply ring. As shown in FIG. 5, ground ring 504 is located below power ring 302. In an embodiment, power ring 302 is square-shaped, similar to power ring 102 shown in FIG. 1. Additionally, ground ring 504 is also square-shaped and has the same dimension as power ring 302, and falls in the same surface. Ground ring 504 may also have the same foot print as power ring 302. Power ring 302 and ground ring 504 may also have other shapes such as a circle.

The positive and negative power supply rails may have various shapes and structures. For example, they may have square patterns, rectangular patterns, or a Manhattan structure, etc. They may be constructed and arranged to have non-right angle turns.

In an embodiment, ring 302 is a positive power supply ring and ring 504 is a negative power supply ring. In another embodiment, ring 302 is a ground ring, and ring 504 is a power supply ring. Typically, ring 504 is located parallel to ring 302 on layer 510. With ring 504 moved to layer 520, more space is free up for placement of circuit modules. Alternatively, the overall circuit layout area could be reduced with the absence of ring 504 from layer 510. Although IC structure 500 is shown to have 2 metal layers, structure 500 may have more than 2 metal layers.

With reference to FIGS. 3 and 5, circuit layout 300 includes a first metal layer 510 and a second metal layer 520. The first layer is used by a plurality of circuit modules such as memory modules 310a-b. The first layer is located above the second layer and includes a conductive grid pattern (Layer 1 conductive grid pattern). Layer 1 conductive grid pattern is formed by ring 302. Alternatively, layer 1 conductive grid is formed by ring 302 and stripe 312. In combination, ring 302 and stripe 312 may form any type of patterns such as a checker board like pattern. Similar to ring 302, layer 1 conductive grid pattern is connected to at least one of the circuit modules. In this manner, power may be delivered to those circuit modules.

Although not shown, circuit layout 300 also includes a layer 2 conductive grid pattern located on second layer 520. Layer 2 conductive grid pattern is formed by ring 504. In an embodiment, layer 2 conductive grid pattern is identical to layer 1 conductive grid pattern. For example, if layer 1 conductive grid pattern has a square shape, then layer 2 conductive grid pattern will also exhibits the same square shape. Further, layer 1 and layer 2 conductive grid patterns should usually match with each other if they are transposed on top of one another. For example, the image of layer 1 conductive grid pattern would be the same as the pattern of layer 2 conductive grid pattern if the image of layer 1 conductive grid pattern is placed on top of layer 2 conductive grid pattern.

Circuit layout 300 also includes vias/metals such that at least one of the plurality of circuit modules is connected to the layer 2 conductive grid pattern. In this way, power or ground may be provided to the circuit modules.

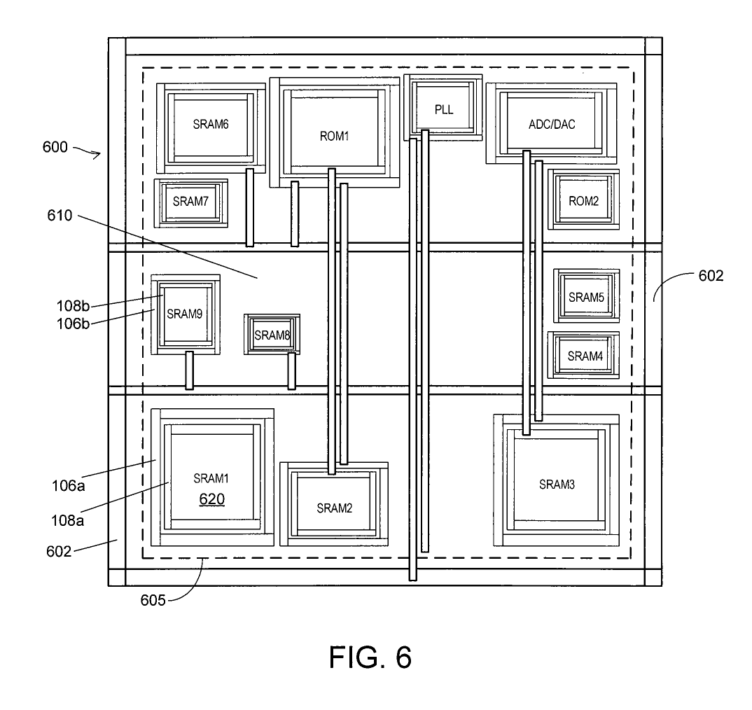

FIG. 6 illustrates a circuit layout of an IC die 600 fabricated in accordance with structure 500 shown in FIG. 5. For the sake of simplicity and clarity, not all metal lines are shown. Enough metal lines are shown so that it is clear that a metal line structure for providing power to the various integrated circuits is simplified with respect to conventional power layout arrangements. IC die 600 includes a plurality of circuit modules such as SRAM1 . . . 9 and ROM1 . . . 2. IC die 600 further includes other circuit components such as a PLL, an analog-to-digital converter, and various logic components. In IC die 600, chip power is distributed to all of the circuit components using a global power rail (also referred to as a “power ring” or “global power ring”) 602. IC die 600 also includes a plurality of local power rings 106a-b and local ground rings such as 108a-b. Each of the local power rings 106 a-b and ground rings is connected to global power ring 602 and a ground ring located at a lower layer (not shown), respectively.

As shown in FIG. 6, IC die 600 includes a perimeter area outside of dashed line 605 and a circuit layout area 610 inside of dashed line 605. The perimeter outside of dashed line 605 extends through all layers of IC die 600, including the top most layer. In IC die 600, global power ring 602 is located in the perimeter area on layer N (corresponding to power ring 302 shown in FIG. 3). Although not shown, global power ring 602 has a corresponding chip ground ring within the perimeter area on a lower layer, layer N−1. In an alternative embodiment, power ring 602 is a positive power supply ring and the corresponding ring within the perimeter area on a lower level is a negative power supply ring. As needed for various IC applications, global power ring 602 and its corresponding ring(s) on a lower level can be at any two different voltages for providing power to the various circuits integrated into IC die 600. In IC die 600, the various local power rings and stripes in the circuit layout area 610 do not have a corresponding ground ring or stripe in a lower layer.

As shown, circuit module 620 has a local power ring 106a and a local ground ring 108a. However, the power and ground overlapping structure, formed by 602 and the chip ground under 602 in this invention, can be also likewise applied to circuit module 620 and any other modules, as long as there are metal layers available in the associated process.

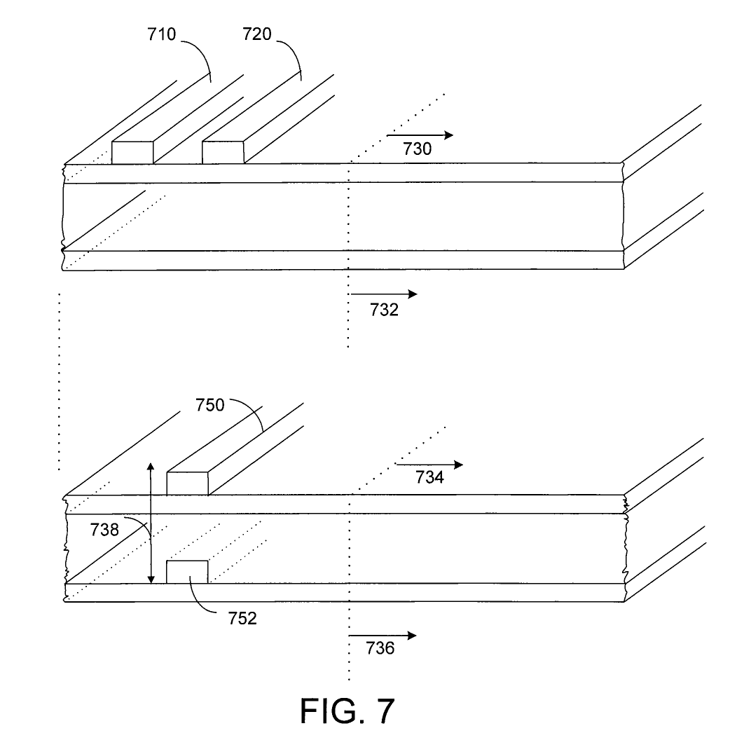

FIG. 7 is a perspective view comparing a traditional integrated circuit power layout with an integrated circuit power layout according to the inventions. The upper portion of FIG. 7 schematically shows a layout of power structures according to traditional designs. The lower portion of FIG. 7 schematically shows a layout of power structures according to the inventions. As illustrated, in the traditional power structure layout power/ground feeding structure 710 and 720 are on the same vertical level and are parallel to one another. In this example, power structure 710 is coupled to a power source Vdd and feeds power to circuits located to its right. Power structure 720 is intended to be coupled to a power source Vss (could be ground potential) and provides a return power path to circuits located to its right. Arrows 730 and 732 in the upper portion of FIG. 7 and arrows 734 and 736 in the lower portion of FIG. 7 point to respective circuit areas. The circuit areas might be populated, for example, with MOS circuits including substrate, diffusion, poly, isolator, and metals, etc. In the lower portion of FIG. 7, arrow 738 indicates that according to the inventions, power structures are placed on different levels of the integrated circuit chip. In this example, power structures 750 and 752 are on different levels. For example power structure 750 might be connected to the Vdd power supply and power structure 752 might be connected to the Vss supply.

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed:

1. An integrated circuit formed on a semiconductor substrate comprising:
a circuit module including at least one conductive metal/via layer, at least one conductive poly-silicon layer, at least one insulator layer, and at least one doped layer;
a first conductive grid pattern formed by a first metal layer being connected to the circuit module; and
a second conductive grid pattern being substantially identical to the first conductive grid pattern, but located on a second metal layer such that an image of the second conductive grid pattern matches an image of the first conductive grid pattern.

2. The integrated circuit of claim 1, wherein the first and the second conductive grid patterns are positive and negative power supply grid patterns, respectively.

3. The integrated circuit of claim 1, wherein the first conductive grid pattern is a positive power supply grid pattern and the second conductive grid pattern is a ground grid pattern.

4. The integrated circuit of claim 1, wherein the first and the second conductive grid patterns are negative and positive power supply grid patterns, respectively.

5. The integrated circuit of claim 1, wherein the first and second conductive grid patterns are constructed and arranged to have a substantially square-shape.

6. The integrated circuit of claim 1, wherein the first and second conductive grid patterns are constructed and arranged to have a substantially rectangular-shaped.

7. The integrated circuit of claim 1, wherein the first and second conductive grid patterns are constructed and arranged to have a Manhattan structure.

8. The integrated circuit of claim 1, wherein the first and second conductive grid patterns are constructed and arranged to have non-right angle turns.

9. The integrated circuit of claim 1, wherein:
each of the layers has a perimeter area and a circuit layout area; and
the first and second conductive grid patterns are located in at least one perimeter area; and
the circuit module is located in at least one circuit layout area.

10. The integrated circuit of claim 1, further comprising:
an insulating layer located between the first and second conductive grid patterns.

11. The integrated circuit of claim 1, wherein the circuit module is connected to the first and second conductive grid through vias/metals.

12. An integrated circuit formed on a semiconductor substrate comprising:
a plurality of circuit blocks including conductive metal/via layers, conductive poly-silicon layers, insulator layer, and doped N/P type layers;
a plurality of positive power supply rails on a first metal layer, wherein each circuit block is connected to at least one positive power supply rail; and
a plurality of negative power supply rails on a second metal layer, wherein the second layer is below the first layer, and a first of the plurality of negative power supply rails is routed such that it tracks a first of the plurality of positive power supply rails above it.

13. The integrated circuit of claim 12, wherein at least one circuit module is connected to the first/second conductive grid through vias/metals.

14. The integrated circuit of claim 12, wherein the positive and negative power supply rails are constructed and arranged to have square patterns.

15. The integrated circuit of claim 12, wherein the positive and negative power supply rails are constructed and arranged to have rectangular patterns.

16. The integrated circuit of claim 12, wherein the positive and negative power supply rails are constructed and arranged to have a Manhattan structure.

17. The integrated circuit of claim 12, wherein the positive and negative power supply rails are constructed and arranged to have non-right angle turns.

18. The integrated circuit of claim 12, wherein:
each of the a layers has a perimeter area;
a each of the layers has a circuit layout area;
the positive and negative power rails are located in at least one perimeter area; and
a circuit block is located in at least one circuit layout area.

19. The integrated circuit of claim 12, further comprising:
an insulating layer located between a positive supply rail and a negative power supply rail.

20. The integrated circuit of claim 12, wherein at least one circuit block is connected to the positive/negative power rail through vias/metals.

21. An integrated circuit on a multi-layer semiconductor substrate comprising:
a first layer including a plurality of circuit blocks;
a plurality of positive power supply rails on the first layer, wherein each circuit block is connected to at least one positive power supply rail; and
a plurality of negative power supply rails on a second layer, wherein the second layer is below the first layer, and a first of the plurality of negative power supply rails is routed such that it tracks a first of the plurality of positive power supply rails above it, and wherein each of the circuit blocks is connected to at least one positive/negative power supply rail through vias/metals;
an insulating layer located between the positive and negative power supply rails.
